(19) United States
(12) Patent Application Publication
(10) Pub. No.: US 2002/0045355 A1
(43) Pub. Date: Apr. 18, 2002

(54) Method of manufacturing a semiconductor device having a silicide layer

(75) Inventors: Seung-Pil Chong, Seoul (KR); Kyu-Hwan Chang, Kyungki-do (KR); Yaung-Min Kwon, Suwon-City (KR); Sang-Lock Hah, Seoul (KR)

Correspondence Address: MILLS & ONELLO, ELEVEN BEACON STREET, SUITE 605, BOSTON, MA, 02108, US

(73) Assignee: Samsung Electronics Co., Ltd.

(21) Appl. No.: 09/771,242

(22) Filed: Jan. 26, 2001

(30) Foreign Application Priority Data
Jan. 29, 2000 (KR) 00-4465

(51) Int. Cl. H01L 21/302; H01L 21/461

(52) U.S. Cl. 438/721

(57) ABSTRACT

A method of manufacturing a semiconductor device such as a contact structure and a gate structure having a silicide layer comprises the steps of: forming a contact hole for exposing a part of the silicon substrate by etching a part of an interdielectric layer formed on a silicon substrate; and first cleaning an exposed surface of the silicon substrate, comprising the steps of: forming a reactive layer by supplying a hydrogen gas in a plasma state and a fluorine-series gas to the silicon substrate and by chemically reacting with an oxide film formed on the exposed surface of the silicon substrate; and annealing to cause the reactive layer to be removed by vaporizing the reactive layer; forming a silicide layer on the surface of the silicon substrate exposed in the contact hole; second cleaning comprising the steps of: forming a reactive layer by supplying a hydrogen gas in a plasma state and a fluorine-series gas to the silicon substrate and by chemically reacting with an oxide film formed on the exposed surface of the silicide layer; and annealing to cause the reactive layer to be removed by vaporizing the reactive layer; and charging a metal layer in the contact hole, in which the silicide layer is formed. In case of the gate structure, the cleaning processes are performed by the same principle before and after forming the silicide layer on a gate electrode material. Accordingly, according to the present invention, the underlying layer of a native oxide film is not damaged or contaminated, and an effective cleaning is performed, thereby improving the reliability of the semiconductor device.

### BACKGROUND OF THE INVENTION

1. Field of the Invention

The present invention relates to a method of manufacturing a semiconductor device, and more particularly, to a method of manufacturing a contact structure and a gate structure having a silicide layer.

2. Description of the Related Art

As patterns formed on semiconductor integrated circuits become smaller, demand for decrease in resistance and capacitance related to interconnections become stronger. RC time constants of the interconnections, in particular, are closely related to the operation speed of circuits in a metal-oxide-semiconductor (MOS) structure. In general, aluminum (Al) having a low resistance and a high electric conductivity is used as an interconnection material. However, since the melting point of Al is low, it is not possible to perform an oxidation process or an annealing process or the like at 500° C. or higher. To overcome this problem, silicide materials having low electric resistance and excellent thermal stability is proposed. Since silicide is the mixture MSiₓ of a refractory metal, a low resistance substance, and silicon offers a low electric resistance, excellent thermal stability even at a high temperature, excellent workability, excellent adhesiveness to Al, and excellent electro-migration resistivity, silicide is used as a contact structure and a gate structure in semiconductor devices, as an attractive material.

In a conventional contact structure of the semiconductor devices, a silicide layer is formed between a silicon substrate and Al in a contact hole, and the silicide layer prevents a phenomenon known as “Al spiking” from occurring. Al spiking occurs due to migration of Al into a dopant-implanted layer in the silicon substrate, and destroys shallow junctions. The silicide layer is further employed as an intermediate for reducing contact resistance.

A typical process for manufacturing the silicide layer comprises the steps of: forming a contact hole after etching a predetermined portion of an interdielectric layer formed on the silicon substrate; depositing a material for forming silicide on the entire surface of the substrate including the contact hole; and silicifying the material for forming silicide contacted with the silicon substrate by heat treatment. Here, after removing a non-silicified and non-reactive material, the contact hole is charged into a conductive film such as Al etc.

Meanwhile, the surface of the silicon substrate exposed in the contact hole readily reacts with air or with an oxygen atmosphere, and thereby, a silicon dioxide (SiO₂) film is formed. The native oxide film is known to lower the electric conductivity as an insulating material and thereby increases the contact resistance, and disturbs the subsequent formation of the silicide layer. A hydrofluoric acid (HF) cleaning solution is usually used to remove the native oxide film on the silicon substrate.

On the other hand, the native oxide film is formed on the silicide layer even before depositing the subsequent conductive film such as Al etc. after forming the silicide layer, and at this time, the native oxide film is removed by RF sputtering process. However, this process causes damage to the silicide layer on a lower portion of the native oxide film..

Meanwhile, a polycide structure forming the silicide layer on a poly-silicon, a material for forming a gate, is widely used in the gate structure of the semiconductor devices, and even in this case, a wet cleaning using the HF cleaning solution or RF sputtering process is performed to remove the native oxide film or contaminants formed on the surface of the polysilicon and the silicide layer before and after forming the silicide layer on the polysilicon.

In general, in the wet cleaning process using the HF cleaning solution, it is possible for a high etching selection ratio between the native oxide film and the silicon substrate to be maintained, and it is advantageous that the surface of a silicon wafer is covered with a protective film made of hydrogen (H) after cleaning the native oxide film, however, in case of HF cleaning, it is not possible to perform an in situ process. As a result, it is not easy to control contamination following the cleaning process, and time required for the process is increased, and since a process of drying the wafer should be performed after the cleaning process, it is not possible to control various contamination during a dry process. Also, since in the case of cleaning a small and deep contact hole, it is difficult for to cause the cleaning solution to flow into or out the contact hole through the viscosity of the cleaning solution itself, the removal of the oxide film is not complete, and it is not easy to remove residues after the cleaning process.

### SUMMARY OF THE INVENTION

To solve the above problems, it is an object of the present invention to provide a method of manufacturing a semiconductor device having a silicide layer comprising a cleaning process, in which a silicon substrate or silicide layer, an underlying layer, is not damaged or contaminated and a contaminant or a native oxide film on the surface of the silicon substrate or silicide layer can be effectively cleaned.

Accordingly, to achieve the above object, according to an embodiment of the present invention, there is provided a method of manufacturing a semiconductor device having a silicide layer. The method of manufacturing a semiconductor device having a silicide layer is forming a contact structure containing the silicide layer. A part of an interdielectric layer formed on a silicon substrate is etched, and a contact hole for exposing a part of the silicon substrate is formed. Next, a surface contaminant remained on an exposed surface of the silicon substrate and a native oxide film are first cleaned and removed by supplying a hydrogen gas in a plasma state and a fluorine-series gas to the silicon substrate. Subsequently, a silicide layer is formed on the surface of the silicon substrate exposed in the contact hole, and a surface contaminant remained on the surface of the silicide layer and a native oxide film are second cleaned and removed by supplying a hydrogen gas in a plasma state and a fluorine-series gas to the silicon substrate before charging a metal layer in the contact hole in the same method as that of first cleaning.

The steps of first and second cleaning comprises the steps of: forming a reactive layer by supplying a hydrogen gas in a plasma state and a fluorine-series gas to the silicon substrate and by chemically reacting with an oxide film formed on the exposed surface of the silicon substrate; and annealing so that the reactive layer may be removed by vaporizing the reactive layer.

In the steps of first and second cleaning, preferably, the steps of forming the reactive layer and annealing are consecutively performed in a process chamber, and the process chamber includes a down-flow module for supplying a process gas after the process gas is made into a plasma, and an annealing module having a heating means, and in each of the steps of first and second cleaning, the step of forming the reactive layer can be performed in the down-flow module, and the step of annealing can be formed in the annealing module.

On the other hand, in order to achieve the above object of the present invention, according to another embodiment of the present invention, there is provided a method of manufacturing a semiconductor device having a suicide layer. The method of manufacturing a semiconductor device having a silicide layer relates to a gate structure containing the silicide layer. First, a material for forming a gate containing silicon on a silicon substrate, in which a gate dielectric layer is formed, is formed. Next, a surface contaminant or a native oxide film remained on the surface of the material for forming a gate is first cleaned and removed by supplying a hydrogen gas in a plasma state and a fluorine-series gas to the silicon substrate.

Subsequently, a silicide layer is formed on the material for forming a gate. Even after forming the silicide layer, before forming a subsequent layer, a surface contaminant or a native oxide film remained on the surface of the silicide layer is second cleaned and removed by supplying a hydrogen gas in a plasma state and a fluorine-series gas to the silicon substrate.

According to the present invention, since in the contact structure or gate structure, the surface contaminant or the native oxide film remained on the surface of the silicon substrate or silicide layer is chemically reacted by supplying a hydrogen gas in a plasma state and a fluorine-series gas to the silicon substrate, and then, its reactive resultant is vaporized and removed by an annealing process, the damage of the silicon substrate or silicide layer can be minimized, and a surface cleaning can be effectively performed, and thereby, high characteristics of the silicide layer in the contact structure or gate structure can be obtained, and a reliable semiconductor device can be manufactured.

### BRIEF DESCRIPTION OF THE DRAWINGS

The above object and advantages of the present invention will become more apparent by describing in detail preferred embodiments thereof with reference to the attached drawings in which:

FIG. 1 is a schematic diagram illustrating an apparatus for manufacturing a semiconductor for implementing a method of manufacturing a semiconductor device according to an embodiment of the present invention;

FIG. 2 is a plane view illustrating an upper end of a vacuum chamber of the apparatus for manufacturing a semiconductor of FIG. 1;

FIG. 3 is a schematic plane view illustrating another apparatus for manufacturing a semiconductor for implementing the method of manufacturing a semiconductor device according to an embodiment of the present invention;

FIG. 4 is a schematic diagram illustrating the configuration of a down-flow module of FIG. 3;

FIG. 5 is a flow chart illustrating the method of manufacturing a semiconductor device according to a first embodiment of the present invention;

FIGS. 6 through 9 are process sectional views according to the flow chart of FIG. 5;

FIG. 10 is a flow chart illustrating the method of manufacturing a semiconductor device according to a second embodiment of the present invention; and

FIGS. 11 through 14 are process sectional views according to the flow chart of FIG. 10.

### DETAILED DESCRIPTION OF PREFERRED EMBODIMENTS

In embodiments of the present invention, a cleaning process is performed in an apparatus for dry cleaning for manufacturing a semiconductor device disclosed in Korean Application No. 99-46365, which is invented by part of inventors of the present invention and applied for a patent, and incorporated herein by reference.

<Apparatus for dry cleaning capable of performing cleaning process of the present invention>

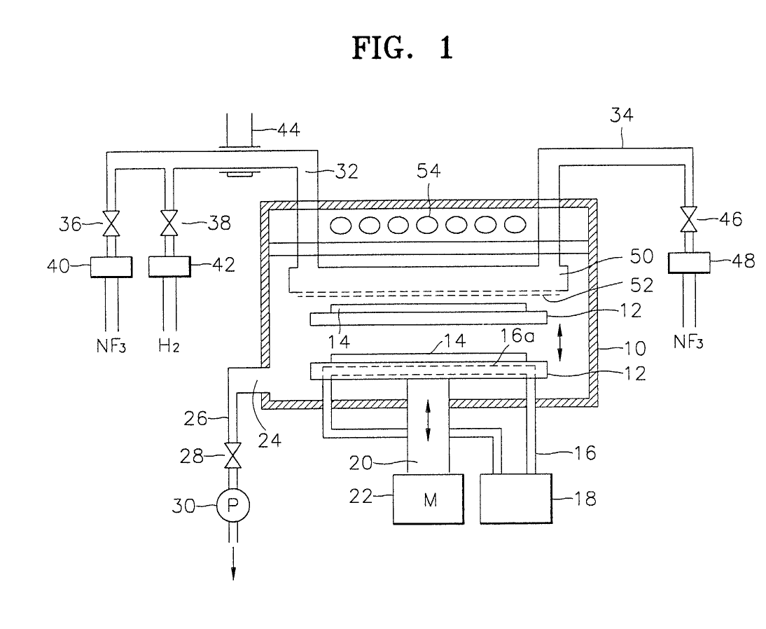

FIG. 1 is a schematic diagram illustrating an apparatus for dry cleaning for manufacturing a semiconductor device capable of performing a dry cleaning process in embodiments of the present invention, the apparatus for dry cleaning includes a vacuum chamber 10 constituted to perform the process at a vacuum atmosphere, a remote-type plasma generator 44 for flowing into the vacuum chamber 10 after transforming a reaction gas into a plasma state, a gas diffuser 50 and 52, a heater 54 for consecutively performing an annealing process in the same chamber, and a driving unit of a susceptor 12 for controlling the position of a silicon wafer in the vacuum chamber 10.

Referring to FIG. 1, the apparatus for dry cleaning for manufacturing a semiconductor device will be described in more detail. In a process for manufacturing a semiconductor device, a susceptor 12, on which a silicon wafer 14 is loaded for undergoing the cleaning process after performing a specific process, is installed in the middle of the lower end of the vacuum chamber 10, and the susceptor 12 is moved from the lower end to the upper end of the vacuum chamber 10 or from the upper end to the lower end of the vacuum chamber 10 to through a upward and downward moving shaft 20 by operation of a motor 22 (see arrow ( [symbol] )). For reproduction of the process, a cooling line 16a for supplying a coolant or cooling gas is installed in the susceptor 12 so as to readily control the temperature of the silicon wafer 14, and a first pipe 16 for supplying the coolant or cooling gas from a coolant or cooling gas supplying device 18 is connected to the cooling line 16a. The temperature of the silicon wafer 14 is adjusted by the temperature of the susceptor 12, and the temperature of the susceptor 12 is adjusted by the temperature of the coolant or cooling gas supplied through the cooling line 16a.

The reaction gas is supplied into the vacuum chamber 10 through the gas diffuser 50 and 52, and the gas diffuser includes a preparatory chamber 50, in which the reaction gas is supplied from second and third pipes 32 and 34 installed out of the vacuum chamber 10, and a porous plate 52 for being connected to the end of the preparatory chamber 50 and for supplying gas all over the inside of the vacuum chamber 10. The second pipe 32 serves to supply gas in the state of a plasma, and a hydrogen gas supply source (marked “H₂”) and fluorine-series gas supply source (marked “NF₃”) are connected to one end of the second pipe 32. Mass flow controllers 40 and 42 for controlling a quantity of gas and switching valves 36 and 38 are installed in each of the hydrogen gas supply source and fluorine-series gas supply source. A microwave guide 44, as a plasma generator for exciting gas passing through the switching valves 36 and 38 and the mass flow controllers 40 and 42 in the hydrogen gas supply source and fluorine-series gas supply source, into a plasma state, is installed between another end of the switching valves 36 and 38 and the second pipe 32. The third pipe 34 serves to supply a fluorine-series gas in a natural state, and the fluorine-series gas supply source (marked “NF₃”) is connected to one end of the third pipe 34. A switching valve 46 and a mass flow controller 48 are connected between another end of the third pipe 34 and the fluorine-series gas supply source.

Here, the position, and type, of the gas sources can be varied according to applied processes, rather than that the hydrogen gas supply source (H₂)and fluorine-series gas supply source (NF₃) are limited to sources for supplying only a hydrogen gas or fluorine-series gas, and as occasion demands, an argon (Ar) gas as well as a nitrogen (N₂) gas can be further supplied.

An exhaust port 24 is installed in the lower portion of the vacuum chamber 10 and is a path for exhausting air such as gas in the vacuum chamber 10 in order to keep the vacuum chamber 10 in a vacuum state. A fourth pipe 26 is connected to the exhaust port 24, and a switching valve 28 and a vacuum pump 30 are installed in the fourth pipe 26.

The pressure in the vacuum chamber 10 during supplying of the reaction gas (also referred to as “down-flow”) is automatically adjusted by a smart valve (not shown) installed in the lower portion of the vacuum chamber 10, and the pressure in the vacuum chamber 10 during down-flowing is maintained at 0.1 Torr˜10 Torr in order to easily adsorb the reaction gas on the silicon wafer 14.

The heater 54 for annealing the silicon wafer 14 is installed between ceilings of the preparatory chamber 50 and vacuum chamber 10. The heater 54 consists of a lamp or laser. A neodymium (Nd)-YAG laser, a carbon dioxide (CO₂) laser, or an excimer laser etc. can be employed.

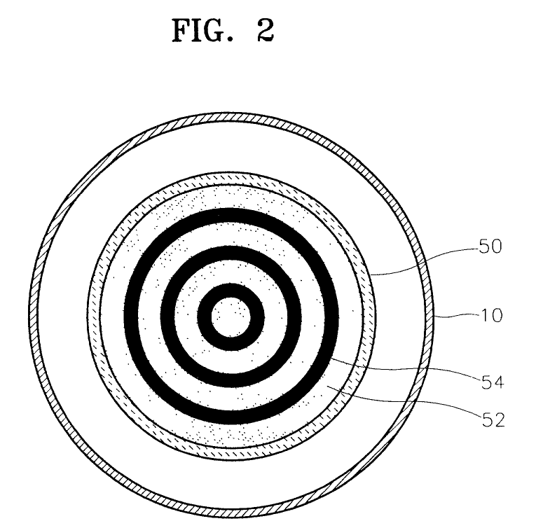

FIG. 2 is a plane view illustrating an upper end of a vacuum chamber 10 of FIG. 1, and reference numerals 10, 50, 52, and 54 denote a vacuum chamber, a preparatory chamber, a porous plate, and a heater, respectively. The heater 54 is installed in the shape of a circle, repeatedly-arranged of the same circle and concentric circle as that of the silicon wafer in order to uniformly heat the silicon wafer 14.

FIG. 3 is a plane view illustrating another apparatus for dry cleaning for performing a dry cleaning process in embodiments of the present invention, and reference numerals 60, 62, 64, 66, and 68 denote a vacuum chamber, a rotary motor, a loading/unloading and post-processing module, a down-flow module, and an annealing module, respectively. As a modified example of the apparatus for dry cleaning of FIG. 3, the down-flow module 66 and the annealing module 68 can be repeatedly installed in a single vacuum chamber 60.

Referring to FIG. 3, a rotary plate (not shown) is installed in the lower end of the vacuum chamber 60, and the rotary motor 62 for rotating the rotary plate is installed in the middle of the rotary plate. The loading/unloading and post-processing module 64, the down-flow module 66, and the annealing module 68 are installed on the rotary plate around the rotary motor 62 centering the rotary motor 62.

A vacuum system (not shown) is installed in the vacuum chamber 60 so as to enable processing at a vacuum atmosphere, and the rotary plate is installed in the vacuum chamber 60 to provide detailed control over the position of the silicon wafer in the vacuum chamber 60. That is, since the position of the silicon wafer can be changed from one module to another module by moving the rotary plate, it is possible to consecutively perform down-flow and annealing processes in the same chamber and to consecutively and repeatedly perform the down-flow and annealing processes.

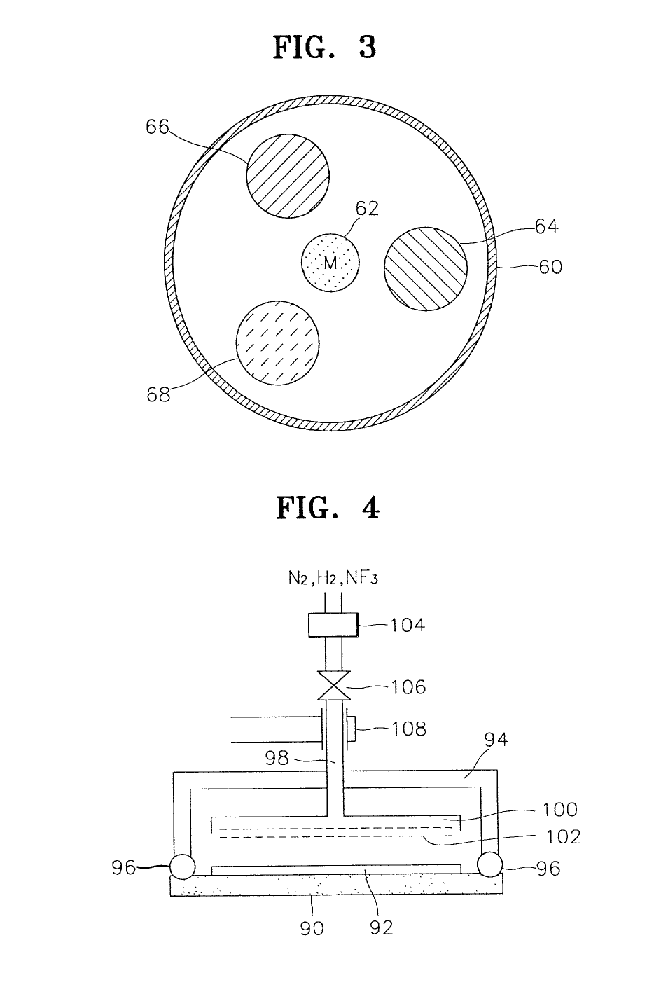

FIG. 4 is a sectional view illustrating the configuration of a down-flow module of FIG. 3. The down-flow module 66 includes a susceptor 90 installed in the rotary plate to load a silicon wafer 92, a chamber 94 for down-flowing capable of upward and downward movement, which is installed on the upper portion of the susceptor 90 so as to cover the susceptor 90, a gas diffuser 100 and 102 for supplying a used gas to the wafer loaded on the susceptor 90, which is installed the upper end in the chamber for down-flowing 94, and a gas supply pipe 98 connected to the gas diffuser 100 and 102. Guide rings 96 are installed in the end of the chamber for down-flowing 94 in order to adhere the chamber closely to the rotary plate during down-flowing 94, in which the susceptor 90 is installed.

The gas diffuser 100 and 102 includes a gas supply line 100 to which a gas is supplied from the gas supply pipe 98, and a porous plate 102 installed in the end of the gas supply line 100 so as to supply the reaction gas to all portions of the silicon wafer 92.

Reaction gas supply sources (marked N₂, H₂, and NF₃) are installed in one end of the gas supply pipe 98. The reaction gas supplied from the reaction gas supply source passes through a mass flow controller 104 installed in the gas supply pipe 98 and thereby adjusts a mixed quantity of the reaction gas and passes through a switching valve 106. Since a microwave guide 108 is installed between the switching valve 106 and the gas supply pipe 98, the reaction gas passing through the gas supply pipe 98 is excited into a plasma state.

The annealing module 68 (see FIG. 3) includes a susceptor for loading a silicon wafer, a chamber for annealing capable of upward and downward movement, which is installed in the upper portion of the susceptor to cover the susceptor, and a heater for annealing the silicon wafer, which is installed in the upper end in the chamber for annealing. Also, guide rings are installed in the end of the chamber for annealing in order to adhere the chamber for annealing closely to a rotary plate, in which the susceptor is installed. The heater is installed in a circular shape repeatedly-arranged of the same circle and concentric circle as that of the silicon wafer in order to uniformly heat the silicon wafer, as shown in FIG. 2.

The loading/unloading and post-processing module 64 (see FIG. 3) is constituted in the shape of a chamber for loading/unloading or post-processing the wafer to be processed.

As described later, according to a method for dry cleaning using a mixed gas of the hydrogen gas and fluorine-series gas in a plasma state, (NH)ₓ(SiF)ₓ, that is, a reactive layer in the shape of (NH₄)₂SiF₆ is formed by a chemical combination of a native oxide film formed on the surface of the silicon wafer during a down-flow process and the mixed gas, and subsequently, the reactive layer is vaporized and removed by an annealing process in situ performed in the same chamber.

In a case where the apparatus of FIGS. 1 and 2 are used for cleaning, the annealing process is performed by moving the susceptor into the upper end of the vacuum chamber after the down-flow process is performed in the lower end of the vacuum chamber, and in this case, the temperature in the vacuum chamber becomes unstable, or else it is difficult to uniformly adjust the temperature of the silicon during each process, and problems such as the introduction of particles into the vacuum chamber can occur.

The apparatus for cleaning of FIGS. 3 and 4 address this issue. The down-flow module 66 and annealing module 68 are installed within one vacuum chamber in order to minimize the adverse effects of performing the down-flow process and annealing process in separate modules. Also, in this case, since the down-flow process and annealing process can be consecutively and repeatedly performed in the same chamber, the apparatuses are useful in a case where the entire oxide film cannot be removed in a single cleaning process.

<Embodiment 1>

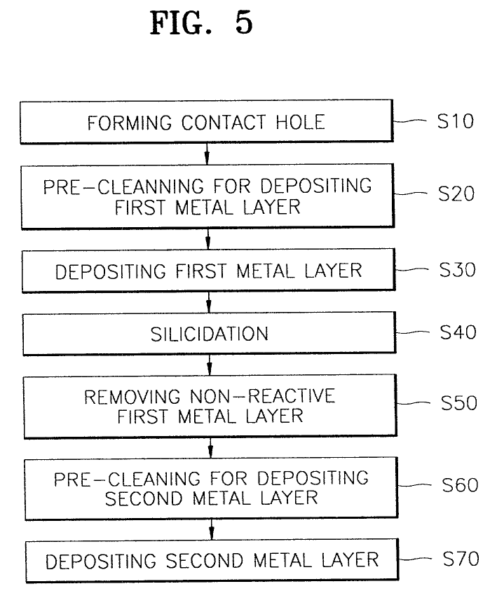

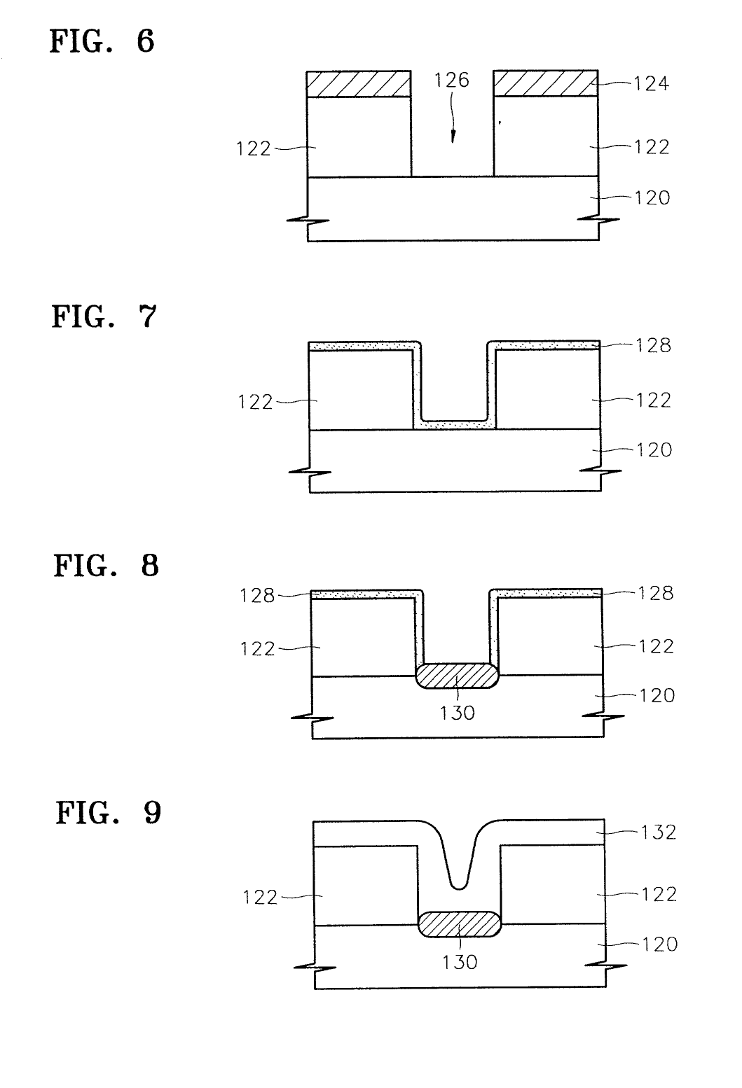

A first embodiment of the present invention relates to a method for manufacturing a contact structure containing a silicide layer. FIG. 5 is a flow chart illustrating the method of manufacturing a semiconductor device according to the first embodiment of the present invention, and FIGS. 6 through 9 are process sectional views according to the flow chart of FIG. 5.

Referring to FIGS. 5 through 9, a photoresist pattern 124 for restricting a contact hole as an etching mask is formed using a photolithography technology following formation of an interdielectric layer 122 on a silicon substrate 120. The interdielectric layer 122 may comprise an oxide film or a nitride film or a multiple-layer film. When the interdielectric layer 122 is etched using the photoresist pattern 124, a contact hole 126 for exposing the surface of the silicon substrate 120 is formed (step S10).

Subsequently, a pre-cleaning process for depositing a first metal layer for removing a surface contaminant or a native oxide film remaining on an exposed surface of the silicon substrate 120 in the contact hole 126 is performed before deposit of the first metal layer as a material for forming a suicide in the contact hole 126 (step S20). The pre-cleaning process serves to effectively remove the native oxide film or the surface contaminant, which is spontaneously formed on the surface of the silicon substrate 120, without damaging the lower silicon substrate 120 and is performed not by the conventional method for wet drying using a HF cleaning solution, but instead by a method for dry cleaning using gas.

In further detail, the cleaning process comprises the steps of: changing the native oxide film into a reactive layer such as (NH)ₓ(SiF)ₓ, that is, (NH₄)₂SiF₆ by supplying a hydrogen gas and fluorine-series gas to the silicon substrate 120, on the surface of which the native oxide film is formed, and by chemically reacting a supplied reaction gas with the native oxide film; and vaporizing the reactive layer generated by the chemical reaction by annealing.

Here, the hydrogen gas is supplied in a plasma state, and the fluorine-series gas can be used in a natural state or plasma state. That is, after making a mixed gas, in which the hydrogen gas and fluorine-series gas are mixed at a predetermined ratio, into a plasma state, the hydrogen gas and fluorine-series gas can be supplied to the silicon wafer, or the fluorine-series gas in a natural state can be supplied to the silicon wafer while the hydrogen gas in a plasma state can be supplied to the silicon wafer. Here, NF₃, SF₆, and CIF₃ or the like are preferably used as the fluorine-series gas.

The annealing is performed using a heater such as a lamp or laser. Here, since the object of the annealing is to vaporize by-products formed on the surface of the silicon wafer, that is, the reactive layer, it is more effective to install the heater so as to impart heat on the upper portion of the silicon wafer.

When the hydrogen gas in a plasma state and fluorine-series gas (for example, a mixed ratio of NF₃ gas to the hydrogen plasma gas is set at 0.1˜100.) are supplied to the silicon wafer, a feed gas chemically reacts with the oxide film, that is, silicon dioxide (SiO₂), and forms by-products such as (NH)ₓ(SiF)ₓ, in which the feed gas and oxide film are combined in the place where the feed gas is adjacent to the oxide film, that is, (NH₄)₂SiF₆, that is, the reactive layer. After the reactive layer is partly formed, the chemical reaction between the supplied gas and oxide film stops in that the reactive layer serves as a barrier layer to the chemical reaction. When annealing is performed during the state where the chemical reaction between the feed gas and oxide film stops, the reactive layer is vaporized and exhausted.

In the steps of down-flowing and annealing for forming the reactive layer by supplying a gas, it is generally easy for the oxide film to be removed in a single step of the process in the case where the thickness of the oxide film to be removed is as thin as the native oxide film; however, the steps can be repeatedly performed more than one time according to the thickness of the oxide film to be removed.

Meanwhile, in the pre-cleaning for depositing the first metal layer (step S20), the steps of chemically-reacting (in other words, the step of down-flowing, in which the gas is supplied) between the feed gas and oxide film and annealing are consecutively performed in one chamber. For example, in a case where the apparatus for cleaning of FIG. 1 is used, the step of chemically-reacting is performed in the lower end of a vacuum chamber 10, and the step of annealing is performed in the upper end of the vacuum chamber 10, in which the a heater 54 is installed. In the case where the apparatus for cleaning of FIG. 3 is used, the steps of chemically-reacting and annealing are consecutively performed in several process modules, in which are installed in a single vacuum chamber 60. That is, the step of chemically-reacting is performed in a down-flow module 66 in chamber 60, and the step of annealing is performed in an annealing module 68 in chamber 60.

The pre-cleaning process for depositing a first metal layer of the present invention using the apparatuses of FIGS. 1 or 3 will now be described in detail.

### 1) A Method for Cleaning by Using Apparatuses of FIGS. 1 and 2

Referring to FIGS. 1 and 2, any air such as a gas existing in the vacuum chamber 10 is exhausted through exhaust port 24 and the fourth pipe 26 by using a switching valve 28 and a vacuum pump 30 so that the inside of the vacuum chamber 10 may be maintained in a vacuum state, and a silicon wafer 14 is loaded on a susceptor 12 in the state that the susceptor 12 capable of upward and downward motion, which is installed in the lower end of the vacuum chamber 10. The temperature of the susceptor 12 is adjusted and the temperature of the silicon wafer 14 loaded on the upper side of the susceptor 12 is adjusted by supplying a coolant or cooling gas through a cooling line 16a mounted in the susceptor 12.

A hydrogen gas in a plasma state and a gas containing fluorine chemically reacts with the native oxide film formed on the surface of the silicon wafer 14 by supplying the hydrogen gas in a plasma state and the gas containing fluorine into the vacuum chamber 10 (that is, a down-flow process). When the chemical reaction subsides by the formation of the reactive layer, the susceptor 12 is moved into the upper end of the vacuum chamber 10 by using a upward and downward moving shaft 20 and a motor 22. The reactive layer is vaporized by annealing the silicon wafer 14 loaded on the susceptor 12 by operating a heater 54 installed in the upper end of the vacuum chamber 10. The by-products vaporized from the silicon wafer 14 are exhausted through the exhaust port 24 and the fourth pipe 24. The susceptor 12 located in the upper end of the vacuum chamber 10 is then returned into the lower portion of the vacuum chamber 10 by using the upward and downward moving shaft 20 and the motor 22.

The process of supplying the hydrogen gas in a plasma state and the gas containing fluorine into the vacuum chamber 10 may comprise supplying a mixed gas, in which the hydrogen gas and the gas containing fluorine are mixed at a predetermined ratio, into the vacuum chamber 10 after transforming the mixed gas into a plasma state. Alternatively, the process may supply the gas containing fluorine in a natural state to the vacuum chamber 10. Here, in order to increase the effect on the removal of the native oxide film, as occasion demands, an argon (Ar) gas and a nitrogen (N₂) gas in a plasma state can be also supplied to the vacuum chamber 10.

The gas containing fluorine may comprise NF₃, SF₆ or CIF₃ etc., and the mixed ratio of the gas containing fluorine to the hydrogen gas (for example, NF₃) can be properly selected at 0.1˜100. Also, the cooling line 16a is preferably installed in the susceptor 12 so that the temperature of the silicon wafer may be easily controlled for increasing the reproduction of processes, and the temperature of the silicon wafer 14 is uniformly adjusted by a cooling gas supplying device 18 and a thermostat (not shown), preferably, within the range of −25° C. to 50° C. Also, the pressure in the vacuum chamber 10 during the down-flow process is preferably automatically adjusted by a smart control valve (not shown), and the interior of the vacuum chamber 10 during the down-flow process, is kept at 0.1 Torr˜10 Torr by the smart valve. The native oxide film can be completely removed by performing the down-flow process for about 20 to 600 seconds, depending on the thickness of the native oxide film.

The process of annealing is preferably performed for 20 to 600 seconds at a temperature of 100 to 500° C., and during this process, the reactive layer formed by the chemical reaction of the native oxide film and the reaction gas is vaporized. Meanwhile, preferably, the process of annealing is performed in the same chamber as that of the down-flow process, but it is not necessarily limited to this, and the process of annealing can be performed in a separate annealing chamber.

### 2) A Method for Cleaning Using Apparatuses of FIGS. 3 and 4

Referring to FIGS. 3 and 4, a contact hole is formed on a susceptor 90 of a loading/unloading and post-processing module 64 installed in a rotary plate of a vacuum chamber 60 and loads a silicon wafer 92 of which bottom is exposed. The susceptor 90 is moved into the lower portion of a chamber 94 for down-flowing of a down-flow module 66 by driving a rotary motor 62 installed in the middle portion of the rotary plate. The interior of the down-flow module 66 is completely sealed by adhering the chamber for down-flowing 94 closely to the rotary plate using guide rings 96 after moving the chamber for down-flowing 94 into its lower portion. The reactive layer is formed by supplying a hydrogen gas in a plasma state and a gas containing fluorine (fluorine-series gas) into the chamber for down-flowing 94 and by chemically reacting the hydrogen gas in a plasma state and the gas containing fluorine (fluorine-series gas) with the native oxide film on the surface of the silicon wafer 92.

The chamber for down-flowing 94 is moved into the upper portion of the chamber for down-flowing 94, and the susceptor 90 is moved into the lower portion of the chamber for annealing of an annealing module 68 by using the rotary motor 62. Similarly, the interior of the annealing module is completely sealed by adhering the chamber for annealing closely to the rotary plate using the guide rings 96 after the annealing chamber is moved into its lower portion. The reactive layer formed on the surface of the silicon wafer 92 is vaporized by annealing the silicon wafer 92 using the heater installed in the upper end in the chamber for annealing. The reactive layer vaporized from the silicon wafer 92, that is, by-products, are exhausted.

The susceptor 90 is moved into the lower portion of a chamber for loading/unloading and post-processing (not shown) of the loading/unloading and post-processing module 64 after the chamber for annealing is dismounted from the rotary plate by moving the chamber for annealing into its upper portion. The interior of the module for loading/unloading and post-processing is completely sealed by adhering closely to the rotary plate using the guide rings 96 after the chamber for loading/unloading and post-processing is moved into its lower portion. In a case where it is necessary to process the surface of the silicon wafer, a protective film made of hydrogen is formed on its surface by post-processing as a hydrogen gas, and then, the silicon wafer is loaded.

Referring again to FIGS. 5 and 7, a material for forming silicide, i.e. a first metal layer 128, is deposited on a contact hole 126 (step S30), of which the bottom exposed by the pre-cleaning process for depositing a first metal layer (step S20) is cleaned, as described above. A refractory metal having a low electric resistance and a high thermal stability is used as the material for forming silicide, for example, tungsten (W), titanium (Ti), cobalt (Co), nickel (Ni), molybdenum (Mo), tantalum (Ta), platinum (Pt), and palladium (Pd) can be used as the material for forming silicide.

Subsequently, when a silicidation process accompanying heating (step S40) is performed, silicon is continuously supplied from a silicon substrate 120 to the portion contacted with the silicon substrate 120, as shown in FIG. 8, and thereby, a silicide layer 130 having a certain thickness is formed on the bottom of the contact hole 126. Next, when a process of wet or dry etching a non-reactive first metal layer and of removing the first metal layer (step S50) is performed as shown in FIG. 8, the silicide layer 130 exists only in the contact hole 126.

Meanwhile, in this embodiment, the material for forming suicide is heated and silicified following its deposit; however, the silicide layer 130 can alternatively be formed by a chemical deposition or physical deposition by supplying the material for forming silicide and silicon.

Subsequently, the contact hole 126 is buried, or interconnections are formed by depositing a second metal layer 132 in the contact hole 126, in which the silicide layer 130 is formed (step S70). However, since the suicide layer 130 is exposed to, air or to an oxidation atmosphere, until the deposition of the second metal layer 132 is performed in a separate depositing chamber, a native oxide film is thereby formed on the suicide layer 130. Therefore, a pre-cleaning process (step S60) is performed before the second metal layer 132 is deposited.

The pre-cleaning process (step S60) can be performed in the same apparatus and by the same principle as those of the above-described pre-cleaning process for depositing a first metal layer.

<Embodiment 2>

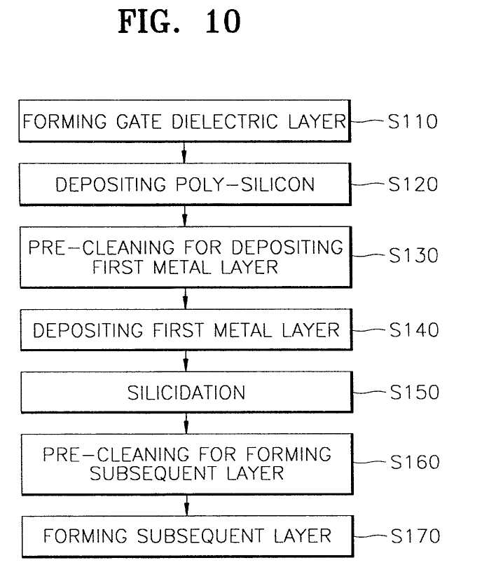

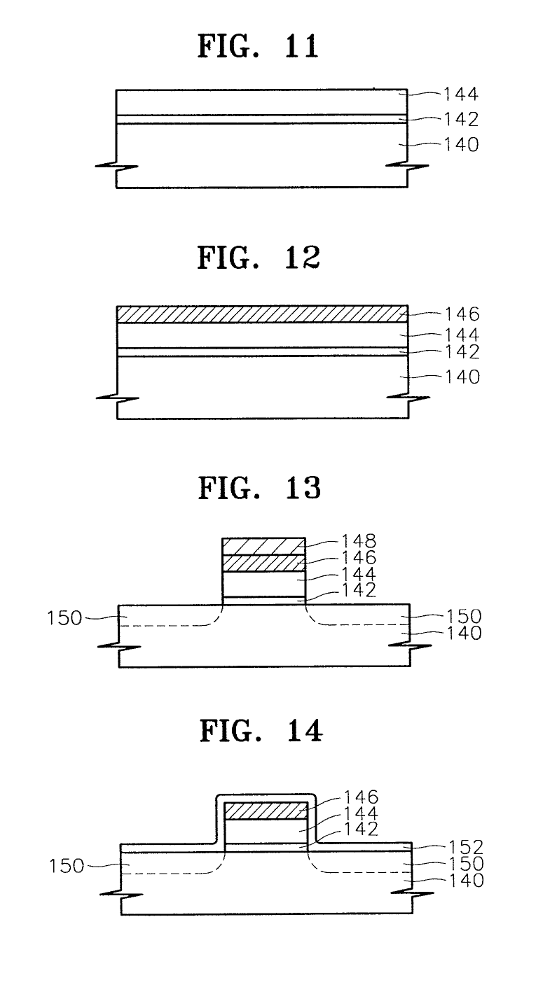

A second embodiment of the present invention relates to a method for manufacturing a gate structure containing a suicide layer, and FIG. 10 is a flow chart illustrating the method of manufacturing a semiconductor device according to the second embodiment of the present invention, and FIGS. 11 through 14 are process sectional views according to the flow chart of FIG. 10.

Referring to FIGS. 10 through 14, a gate dielectric film 142 and a material containing silicon as a material for forming a gate electrode, for example, a poly-silicon layer 144 are sequentially formed on a silicon substrate 140 (steps S110 and S120).

Subsequently, a pre-cleaning process for removing a native oxide film or a surface contaminant formed on the surface of the poly-silicon layer 140 (step S130) is performed before a second metal layer 146 capable of forming silicide on the polysilicon layer 144 is deposited.

The pre-cleaning process (step S130) serves to effectively remove the native oxide film or the surface contaminant, that is spontaneously formed on the surface of the poly-silicon layer 120, without damaging the lower poly-silicon layer 144, and is performed not by the conventional method for wet cleaning using a HF cleaning solution, but instead, by a method for dry cleaning using gas by using the same apparatus and the same principle as those of the first embodiment of the present invention.

Next, the second metal layer 146, as a material for forming silicide, is deposited on the poly-silicon layer 144 (step S140), on which surface cleaning has been performed, and a silicide layer 148 is formed by performing a silicidation process (step S150) in the same manner as that of the first embodiment. Next, the gate structure is formed by a photolithography process in order to form a general polycide gate structure, and a source/drain region 150 is formed by ion-implanting a dopant to the silicon substrate 140. In FIG. 14, reference numeral “152” denotes a dielectric layer formed on the gate structure.

Meanwhile, subsequent layers such as a photoresist or other conductive layers for a gate electrode on the silicide layer 148 can be further formed (step S170), and a pre-cleaning process for forming a subsequent layer for removing the native oxide film formed on the surface of the silicide layer 146 (step S160) is performed by using the same apparatus and the same principle as those of the above-described pre-cleaning process for depositing a first metal layer before forming the subsequent layers.

As described above, in the case where the steps of chemically-reacting and annealing are repeatedly performed in each of cleaning processes, the time required to the processes can be reduced, and simultaneously, the formation of a secondary native oxide film and contamination of particles, which can occur when the silicon wafer is moved from one chamber into another chamber to perform processes for each step, can be prevented. On the other hand, since the cleaning process and the subsequent processes for depositing each metal layer are performed in a separate process chamber, re-oxidation by exposure of the surface of the silicide layer cleaned in the air using equipment, in which a module for the cleaning process and a module for the depositing process are clustered, can be prevented.

As described above, the difference in the method of wet cleaning using a conventional hydrofluoric acid (HF) cleaning solution and the method of dry cleaning according to the embodiments of the present invention will be described as follows.

1) The state of reaction species used for reacting is different. That is, the HF is used in a fluid state, but, in this case, a hydrogen gas and fluorine-series gas containing fluorine are used in a plasma state. Accordingly, in case of the present invention using the reaction species in a gas state, it costs less than that of the conventional method for wet cleaning.

2) In case of the present invention, since each step of the process is consecutively performed in a single chamber, the integration of processes can be increased. Accordingly, the time required for the entire processes can be reduced, and it is easy for various variables in each process during moving to be controlled, and it is advantageous that the size of facility is smaller than that of the conventional method for wet cleaning.

3) It is more advantageous to remove the native oxide film in a small and deep contact hole in the present invention than in the conventional method for wet cleaning. That is, in the conventional method for wet cleaning, there have been many problems in removing the oxide film, because it is difficult to flow the cleaning solution into or out of the contact hole. However, in case of the embodiment of the present invention, since the gas in a plasma state is used, these problems have been addressed.

4) In case of the present invention, since the gas in a plasma state is used, it is easy to control the environment preceding and following the reactions, the environment can be controlled in the optimum state of the surface in the preceding and the following processes.

5) According to the embodiments of the present invention, unlike the conventional method for dry cleaning, in which the oxide film is removed by a method for destructing the combination of particles consisting of the oxide film by an implanted energy of a feed gas, since a method for vaporizing and removing reaction resultants generated from the reaction after inducing the chemical reaction of the feed gas and the oxide film is used in the present invention, it is advantageous to minimize the damage of the lower layer of the oxide film by the energy of the feed gas.

According to the present invention, the method of manufacturing a semiconductor device such as a contact structure or gate structure having a silicide layer can effectively remove the native oxide film and surface contaminant by using the chemical reaction of the reaction gas and the native oxide film before and after forming the silicide layer, and a cleaned underlying layer is not damaged, and thereby, a reliable semiconductor device can be realized.

While this invention has been particularly shown and described with references to preferred embodiments thereof, it will be understood by those skilled in the art that various changes in form and details may be made therein without departing from the spirit and scope of the invention as defined by the appended claims.

What is claimed is:

1. A method of manufacturing a semiconductor device having a silicide layer, comprising the steps of:
forming a specific underlying layer on a semiconductor substrate;
first cleaning an exposed surface of the specific underlying layer, comprising the steps of:
forming a reactive layer by supplying a hydrogen gas in a plasma state and a fluorine-series gas to the semiconductor substrate and by chemically reacting with an oxide film formed on the exposed surface of the specific underlying layer; and
annealing to cause the reactive layer to be removed by vaporizing the reactive layer;
forming a silicide layer on the specific underlying layer; and second cleaning comprising the steps of:
forming a reactive layer by supplying a hydrogen gas in a plasma state and a fluorine-series gas to the semiconductor substrate and by chemically reacting with an oxide film formed on the exposed surface of the silicide layer; and
annealing to cause the reactive layer to be removed by vaporizing the reactive layer.

2. The method of manufacturing a semiconductor device having a silicide layer according to claim 1, wherein the steps of forming the reactive layer and annealing in the steps of first and second cleaning are consecutively performed in a process chamber.

3. A method of manufacturing a semiconductor device having a silicide layer, comprising the steps of:
forming a contact hole for exposing a portion of the silicon substrate by etching a portion of an interdielectric layer formed on a silicon substrate;
first cleaning an exposed surface of the silicon substrate, comprising the steps of:
forming a reactive layer by supplying a hydrogen gas in a plasma state and a fluorine-series gas to the silicon substrate and by chemically reacting with an oxide film formed on the exposed surface of the silicon substrate; and
annealing to cause the reactive layer to be removed by vaporizing the reactive layer;
forming a silicide layer on the surface of the silicon substrate exposed in the contact hole; second cleaning comprising the steps of:
forming a reactive layer by supplying a hydrogen gas in a plasma state and a fluorine-series gas to the silicon substrate and by chemically reacting with an oxide film formed on the exposed surface of the silicide layer; and
annealing to cause the reactive layer to be removed by vaporizing the reactive layer; and providing a metal layer in the contact hole, in which the silicide layer is formed.

4. The method of manufacturing a semiconductor device having a suicide layer according to claim 3, wherein the silicide layer is formed of a material selected 4 from a group consisting of tungsten (W), titanium (Ti), cobalt (Co), nickel (Ni), molybdenum (Mo), tantalum (Ta), platinum (Pt), and palladium (Pd).

5. The method of manufacturing a semiconductor device having a silicide layer according to claim 3, wherein the fluorine-series gas comprises a gas containing fluorine selected from the group consisting of NF₃, SF₆, and CIF₃.

6. The method of manufacturing a semiconductor device having a silicide layer according to claim 3, wherein the hydrogen gas in a plasma state and the fluorine-series gas in a gas state in the steps of first and second cleaning are supplied to the silicon substrate.

7. The method of manufacturing a semiconductor device having a silicide layer according to claim 3, wherein a mixed gas, in which the hydrogen gas and fluorine-series gas in the steps of first and second cleaning are mixed at a predetermined ratio, is transformed into a plasma state and then supplied to the silicon substrate.

8. The method of manufacturing a semiconductor device having a silicide layer according to claim 7, wherein the mixed gas, in which the hydrogen gas and fluorine-series gas are mixed at a predetermined ratio, in a plasma state with nitrogen (N₂) and argon (Ar) is supplied to the silicon substrate.

9. The method of manufacturing a semiconductor device having a silicide layer according to claim 3, wherein the step of forming the reactive layer in the steps of first and second cleaning is performed for 20 to 600 seconds at 0.01 to 10 Torr and at a temperature of −25 to 50° C.

10. The method of manufacturing a semiconductor device having a silicide layer according to claim 3, wherein the step of annealing in the steps of first and second cleaning is performed for 20 to 600 seconds at a temperature of 100 to 500° C.

11. A method of manufacturing a semiconductor device having a silicide layer, comprising the steps of:
providing a material for forming a gate containing silicon on a silicon substrate, in which a gate dielectric film is formed;
first cleaning the surface of the material for forming a gate, comprising the steps of:
forming a reactive layer by supplying a hydrogen gas in a plasma state and a fluorine-series gas to the silicon substrate and by chemically reacting with an oxide film formed on the surface of the material for forming a gate; and
annealing to cause the reactive layer to be removed by vaporizing the reactive layer; forming a silicide layer on the material for forming a gate;
second cleaning the surface of the silicide layer, comprising the steps of:
forming a reactive layer by supplying a hydrogen gas in a plasma state and a fluorine-series gas to the silicon substrate and by chemically reacting with an oxide film formed on the surface of the silicide layer; and
annealing to cause the reactive layer to be removed by vaporizing the reactive layer; and
forming a subsequent layer on the suicide layer.

12. The method of manufacturing a semiconductor device having a silicide layer according to claim 11, wherein the step of forming the silicide layer is performed by a chemical deposition or a physical deposition, in which a refractory metal selected from the group consisting of tungsten (W), titanium (Ti), cobalt (Co), nickel (Ni), molybdenum (Mo), tantalum (Ta), platinum (Pt), and palladium (Pd), is heated.

13. The method of manufacturing a semiconductor device having a silicide layer according to claim 11, wherein the fluorine-series gas comprises a gas containing fluorine selected from the group consisting of NF₃, SF₆, and CIF₃.

14. The method of manufacturing a semiconductor device having a silicide layer according to claim 11, wherein the hydrogen gas in a plasma state and the fluorine-series gas in a gas state in the steps of first and second cleaning are supplied to the silicon substrate.

15. The method of manufacturing a semiconductor device having a silicide layer according to claim 11, wherein a mixed gas, in which the hydrogen gas and fluorine-series gas in the steps of first and second cleaning are mixed at a predetermined ratio, is made into a plasma state and then supplied to the silicon substrate.

16. The method of manufacturing a semiconductor device having a silicide layer according to claim 15, wherein the mixed gas, in which the hydrogen gas and fluorine-series gas are mixed at a predetermined ratio, in a plasma state with nitrogen (N₂) and argon (Ar) is supplied to the silicon substrate.

17. The method of manufacturing a semiconductor device having a silicide layer according to claim 11, wherein the step of forming the reactive layer in the steps of first and second cleaning is performed for 20 to 600 seconds at 0.01 to 10 Torr and at a temperature of −25 to 50° C.

18. The method of manufacturing a semiconductor device having a silicide layer according to claim 11, wherein the step of annealing in the steps of first and second cleaning is performed for 20 to 600 seconds at a temperature of 100 to 500° C.
